(19) United States
(12) Patent Application Publication
(10) Pub. No.: US 2016/0140882 A1
(43) Pub. Date: May 19, 2016

(54) ASSEMBLY OF MULTIPLE FLEXIBLE DISPLAYS

(71) Applicant: FLEXENABLE LIMITED, Cambridge, Cambridgeshire (GB)

(72) Inventors: Andreas Doebelt, Dresden (DE); William Reeves, Willingham, Cambridgeshire (GB)

(21) Appl. No.: 14/904,382

(22) PCT Filed: Jul. 16, 2013
(86) PCT No.: PCT/GB2013/051896

§ 371 Date: Jan. 11, 2016

(51) Int. Cl. G09F 9/302; G09F 9/30; H05K 5/02; G06F 3/041; H05K 1/02; H05K 5/00

(52) U.S. Cl. CPC G09F 9/3026; H05K 1/028; H05K 5/0017; H05K 5/0204; H05K 5/0247; G06F 3/0412; G09F 9/301

(57) ABSTRACT

A display assembly comprising: a magnetic support (18); at least one display panel (12) comprising a magnetic member (14); wherein said at least one display panel (12) is releasably mounted to said magnetic support (18) to form a display area on a front side of said support; and an electronic driver unit mounted to said support wherein said at least one display panel is electrically coupled to said electronic driver unit to drive said at least one display panel.

### FIELD OF THE INVENTION

This invention relates to assemblies of multiple flexible displays, in particular to assemblies of electrophoretic displays.

### BACKGROUND TO THE INVENTION

Providing large-scale displays can be difficult. For example, large plasma and LCD displays are expensive and if used outdoors are prone to damage. Assemblies of smaller displays may present a more cost-effective alternative.

Typically, tiled displays are formed from multiple display units that are laminated onto a backplane, such that the inter-connected display units form a large display area capable of displaying an image continuously across the display area. However, such laminated tiled displays require manufacture (and so may be expensive), and may be available only in pre-set sizes specified by a manufacturer. Moreover, if a fault develops in one of the ‘tiles’ of the display, the permanent lamination of the tile to the backplane and the inter-connection of the tiles mean it is generally not possible to repair a tiled display, and the whole display may need to be discarded.

The present applicant has recognised the need for an alternative method of providing a large-scale display, which addresses the requirements of cost-effectiveness, manufacturing simplicity and ease of repair.

### SUMMARY OF THE INVENTION

According to a first aspect of the invention, there is provided a display assembly comprising: a magnetic support; at least one display panel comprising a magnetic member; wherein said at least one display panel is releasably mounted to said magnetic support to form a display area on a front side of said support; and an electronic driver unit mounted to said support wherein said at least one display panel is electrically coupled to said electronic driver unit to drive said at least one display panel.

An advantage of using a magnetic force to form the assembly is that each display panel can be attached, removed and re-attached to the support an unlimited number of times. A further advantage of the present invention is that the modular assembly allows individual display panels to be disconnected and replaced on demand without damaging any of the other display panels in the assembly or the whole assembly. In contrast, display panels which are laminated onto a backplane cannot be removed or repositioned as the lamination processes permanently fixes the position of the panels on the backplane on first contact of the panel with the backplane.

Said electronic driver unit is mounted to a rear side of said support. In other words, the electronic driver unit is mounted on the opposed side of the support to the display and is thus hidden from view.

Said at least one display panel may comprise an electrical connector which comprises a flexible part. Said support may comprise an aperture through which said flexible part passes to electrically connect said at least one display panel to said electronic driver unit. In this way, the electrical connections are made on the opposed side of the support to the display and are thus hidden from view.

Each display panel may comprise a row electrical connector and a column electrical connector. These column and row connectors may extend beyond the short and long sides of the display panel respectively. The support may comprise an aperture for each of the row and column connectors.

There are preferably a plurality of display panels which together form an array on the support. The support may thus comprise a plurality of apertures which are arranged to enable each of said plurality of display panels to electrical connect to the electronic driver unit. The plurality of panels can be driven separately to provide discrete separate images or to provide one large image. For example, the electronic driver unit may drive each of said plurality of display panels to display separate parts of an image whereby the plurality of display panels together display an image substantially continously across the whole assembly.

Said at least one display panel may comprise an electrophoretic display.

Each of the support, said at least one display panel and said magnetic member are preferably all formed of flexible material to form a flexible assembly. Furthermore, the display assembly may have an overall thickness of between 2 to 55 m, preferably less than 3 mm and possibly less than 2.5 mm or even 2 mm. In this way, a flexible, lightweight and thin display assembly is formed.

The magnetic force between the magnetic member and the magnetic support may be greater than or equal to 40 cN/cm². The force may be approximately 45 cN/cm². The range may be between 40 to 45 cN/cm². The force must be sufficient to prevent the display panel from falling from the support regardless of the angle of the support. However, the force must not be too high to prevent a user being able to dismount a panel from the support.

A foil layer may be coupled between said at least one display panel and said support. The foil layer may increase the magnetic force between the display panel and the support. The foil layer may be approximately 100 μm thick. The foil layer is preferably flexible and may be metallic.

The magnetic member and/or the magnetic support may be formed from polymer foil material. The polymer foil material may be a combination of a polymer such as PVC and a magnetic material such as barium-ferrite or strontium-ferrite. The magnetic member may be in the form of a magnetic layer which may be mounted to a rear face of the display panel. The magnetic layer may be co-extensive with or smaller than the display panel itself. The magnetic support may comprise magnetic areas which are smaller than the area of the display assembly, i.e. the magnetic support need not be magnetic over its entire surface. Where the magnetic layer is smaller than the display panel; these magnetic areas may be arranged on the magnetic support to ensure that the display panels are correctly arranged on the display assembly. This may be achieved because the force of attraction between the display panels and the support is insufficient unless the display panels are correctly aligned with the magnetic areas. This eases the process of display alignment. These magnetic areas (or pockets) may have a thickness greater than the rest of the magnetic support. In this way, the magnetic support may comprise thinner sections which may be rigid and which facilitate rolling the display assembly.

The display assembly may comprise at least two display panels which are mounted adjacent one another on the support and at least one of the display panels may comprise a frame portion which overlaps the adjacent display panel. The display assembly may comprise multiple display panels and the display panels may comprise a frame portion along each side where a display panel is adjacent another display panel. There may be frame portions along at least two, preferably three edges of the display panel. Each frame portion may then overlap an adjacent display panel. The or each frame portion is preferably transparent whereby the display on the display panel is not obscured. The frame portion help to give the impression that there is no gap between the display panels. The underside of the frame portion may comprise an adhesive layer which may reduce unwanted reflections between the overlapping panels. The adhesive layer may be a pressure sensitive adhesive, e.g. a self-wetting adhesive. The adhesive layer is preferably designed to repeatedly stick and unstick and preferably without leaving any residue.

Each display panel may be encapsulated between a front protective layer and a rear protective layer. In this case, the or each frame portion may be formed as a sealed edge between the front protective layer and a rear protective layer. There may be resin between the two layers. Each of the layers and the resin may be transparent. The top layer may be completely clear in which case it may be necessary to also use an antiglare or UV front cover in front of the display. Alternatively, the top layer may be an antiglare layer with reduced transparency to decrease the reflection or glare.

### BRIEF DESCRIPTION OF THE DRAWINGS

The invention is diagrammatically illustrated, by way of example, in the accompanying drawings, in which:

FIG. 1 shows a cross-section of an assembly of multiple flexible display panels according to an embodiment of the invention;

FIGS. 2a and 2b show front and rear views respectively of an assembly of multiple flexible display panels according to an embodiment of the invention;

FIG. 3 shows a flexible display panel according to an embodiment of the invention;

FIGS. 4a and 4b show a prototype embodiment of the assembly of FIG. 1 having an assembly formed from 16 flexible display panels;

FIG. 4c shows an alternative embodiment of the assembly of FIG. 4a;

FIG. 5 shows a block diagram of a system comprising an assembly according to an embodiment of the invention;

FIG. 6 shows a detailed vertical cross-section view through the flexible display panel of FIG. 3

FIG. 7a shows a plurality of encapsulated display panels forming a display assembly,

FIG. 7b shows a schematic cross-section of the encapsulation of FIG. 7a and

FIGS. 7c and 7d show schematic cross-sections of FIG. 7b illustrating the reflections without and with an adhesive layer.

### DETAILED DESCRIPTION OF PREFERRED EMBODIMENTS

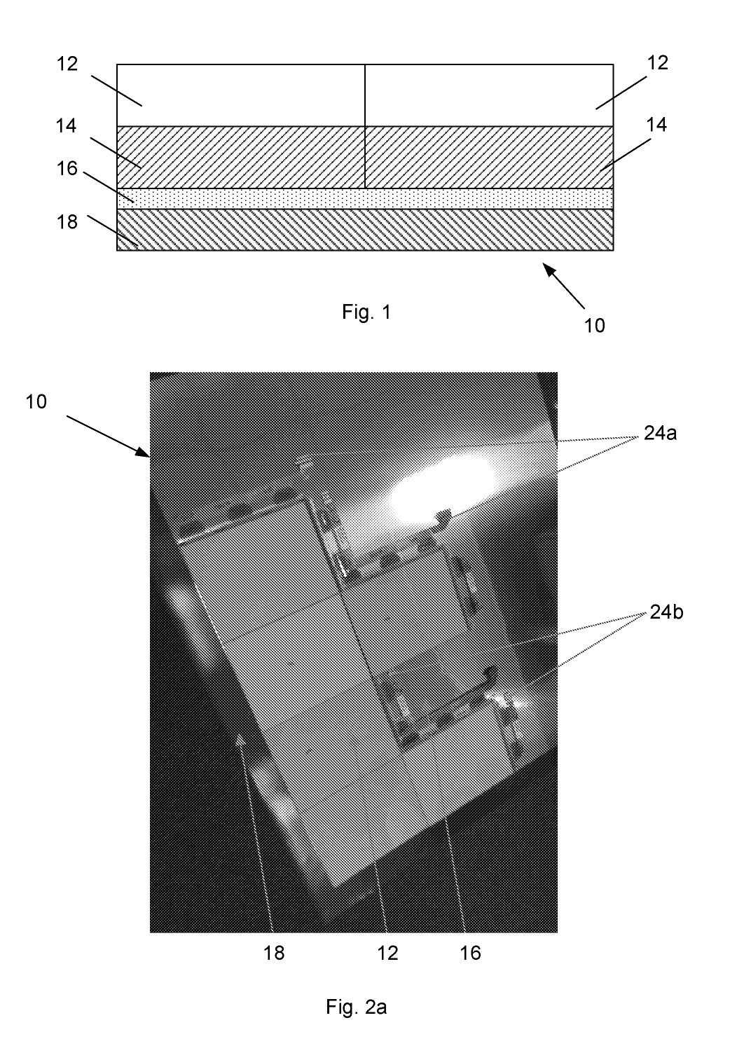

FIG. 1 shows a schematic cross-section of an assembly 10 of multiple display panels according to the present invention. The assembly comprises a magnetic support 18 which may also be termed a backplane and the terms are used into changeable. The magnetic support is large enough to support multiple display panels. The exemplary assembly 10 illustrated here shows two display panels 12 mounted side-by-side on the support. Coupled to the rear of each display panel 12 is a magnetic layer 14 that allows each display panel 12 to be magnetically and releasably mounted onto the support backplane 18. In embodiments, the display panels 12 can be directly mounted onto the support 18 using the magnetic layer 14. In the illustrated embodiment, a thin magnetic metal foil 16 is provided between the magnetic layers 14 and the support 18 in order to increase the magnetic force between the display panel and the backplane.

The metal foil 16 is magnetically attracted to the magnetic layers 14 and consequently, is also magnetically attracted to the support 18.

The display panels 12 are generally formed from a reflective display medium, such as an electrophoretic display. In embodiments, the reflective display medium may be battery operated and therefore, can be stand-alone.

In embodiments, the metal foil 16 may be a 100 μm thick Invar (RTM) foil. The magnetic layer 14 and support 18 may be formed from commercially available materials. In embodiments, the magnetic layer 14 and support 18 may be formed of a sheet material such as a combination of a polymer such as PVC to provide flexibility, and a magnetic material such as barium-ferrite or strontium-ferrite to provide a magnetic force. Preferably, the magnetic force between the magnetic layer 14 and the magnetic support 18 is greater than or equal to 40 cN/cm².

The thickness of the magnetic support 18 can be varied as required. For example, a thin magnetic support 18 provides greater flexibility of the assembly, while a thicker magnetic support 18 may be required when providing a large area display, in order for the backplane 18 to be able to support a large number of flexible display panels 12. In an exemplary embodiment of the assembly formed from sixteen 10.7 inch displays and having a 42 inch overall size (where the measurements are the diagonal dimensions of the display/assembly), the magnetic support 18 may be approximately 0.5 mm thick to provide suitable flexibility and strength. In embodiments, the thickness of the assembly illustrated in FIG. 1 is generally less than 3 mm, and may be less than 2.5 mm. Thus, the assembly is very thin and lightweight. In the exemplary embodiment, the 42 inch assembly display is less than 5 kg in weight. The overall weight of the assembly is dependent on the area of the assembly and that thickness of the magnetic backplane 18 i.e. a larger assembly has a thicker magnetic backplane and a greater weight. Moreover, each layer (display panel, magnetic layer and backplane) is preferably flexible to create a flexible assembly.

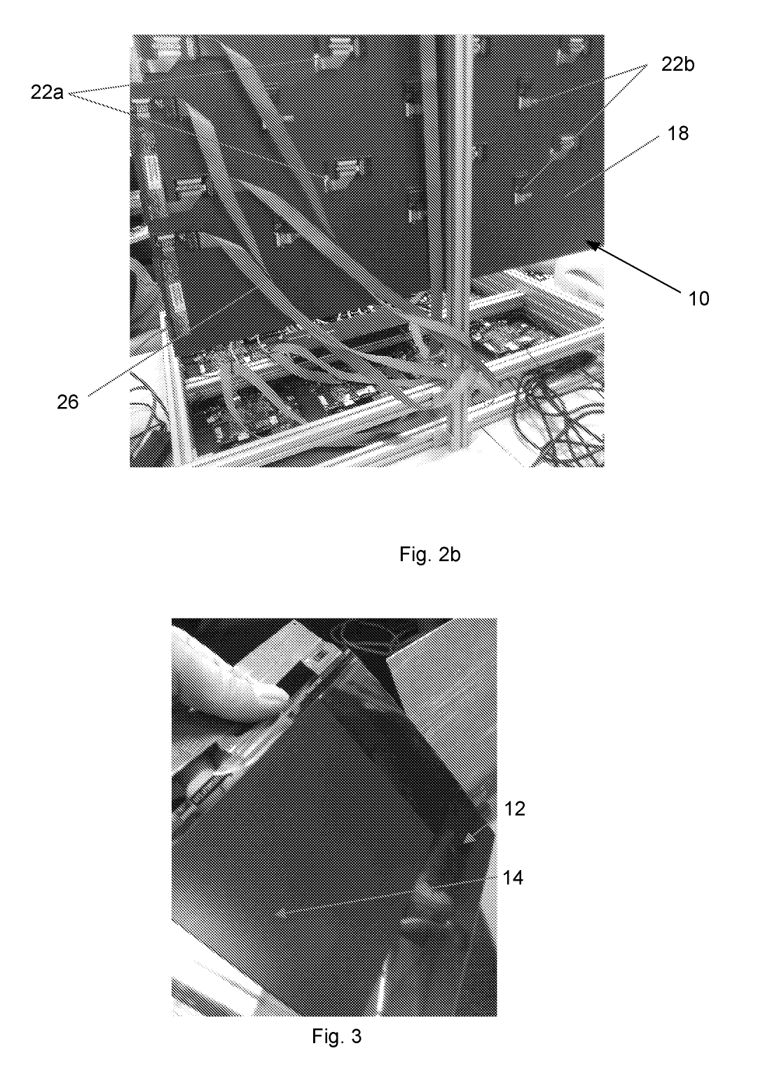

FIGS. 2a and 2b show front and rear views respectively of an embodiment of the assembly 10 of the present invention. As shown in FIG. 2a, a magnetic foil layer 16 is in contact with the magnetic backplane 18 and the foil layer 16 is connected to the backplane 18 by magnetic attraction alone. Flexible display panels 12 each coupled to a laminated magnetic layer (not visible here) are placed on the foil layer 16 to create the assembly 10. In an alternative embodiment, the flexible displays 12 are directly connected to the support 18, without an intermediate foil layer. In both embodiments, the display panels 12 do not need to be assembled in any particular order, such as row by row or column by column. There is a minimal gap between the display panels 12 so that the display panels give the appearance of a larger display.

An advantage of using a magnetic force to form the assembly is that each display panel 12 can be attached, removed and re-attached to the foil layer 16 or to the support 18 an unlimited number of times. This significantly simplifies manufacture of a large-scale display as high-precision techniques are not required to attach the individual display panels to the magnetic backplane. Since each display panel can be repositioned by hand to obtain the desired placement on the magnetic backplane, users can themselves create a large scale display of a particular size as and when desired. In this embodiment, the support 18 is large enough to support an array of four by five panels. In contrast, display panels which are laminated onto a backplane cannot be removed or repositioned as the lamination processes permanently fixes the position of the panels on the backplane on first contact of the panel with the backplane. A further advantage of the present invention is that the modular assembly allows individual display panels to be disconnected and replaced on demand without damaging any of the other display panels in the assembly or the whole assembly. For example, if a fault was discovered in a particular display panel, the faulty panel could be removed and replaced easily.

As shown in FIG. 2a, each display panel comprises electrical connectors 24a, 24b which connect to the driver electronics which may be supported on the support 18. As shown in FIG. 2b, connectors 26 for the driver electronics are mounted on a rear surface of the support, i.e. on the opposed face to the face which supports the display panels. The driver electronics may be mounted to the rear of the support or may be in a separate electronics unit which is placed to the side, below, behind or even remote (i.e. separated from) the display assembly. The connectors 26 may thus include long cables (as shown) to connect to a remote electronics unit. The connectors 26 may comprise a flexible circuit which is laminated, printed or otherwise mounted to the rear of the support.

In the embodiment shown, the support comprises cut-outs or apertures 22a and 22b to allow at least part of the electrical connector for each display panel 12 to pass through the aperture to be connected to the driver electronics on the rear of the backplane 18. This is possible by using for example, a support formed of a plastic or polymer-based material in which apertures or cut-outs can be formed. As an alternative, the electrical connectors for the driver electronics may be mounted on a front face of the support, i.e. sandwiched between the display panels and the support. This alleviates the need for cut-outs in the support.

An advantage of connecting each display panel 12 individually to the driver electronics is that this allows for a modular assembly of display panels. Thus, the panels can be driven separately to provide discrete images or to provide one large image. Alternatively, the source and control electrodes of the displays 12 may be connected together to avoid or reduce any need to connect driver electronics to each individual display unit. In such an embodiment, the driver electronics may be connected to the edge/s of the assembly to drive all of the inter-connected displays that form the assembly.

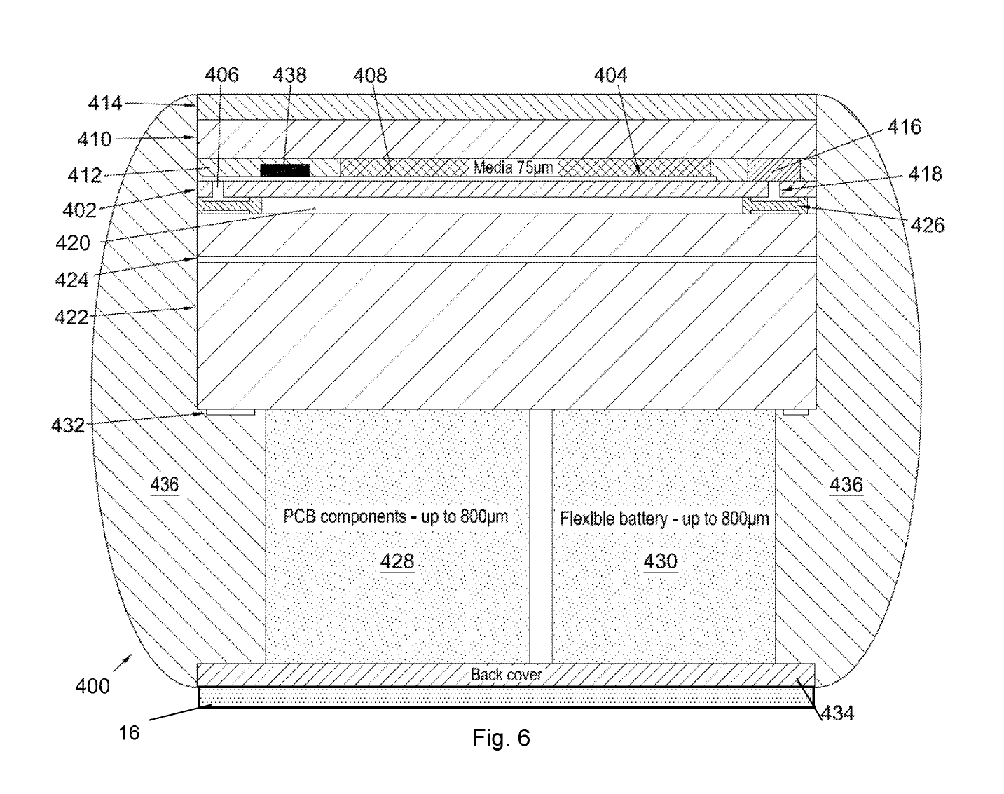

As described in more detail below with respect to FIG. 6, the electronic components of each display panel are distributed over a surface of the panel on a flexible PCB. Connections to row and column electrodes of the display panel may be provided along orthogonal edges of the display panel by column connectors 24a and row connectors 24b. These column and row connectors extend beyond the short and long sides of the display panels respectively. However, the connectors are masked (i.e. hidden behind) adjacent display panels as along as the whole support is covered with display panels. Any connectors extending beyond or at the edge of the support are preferably wrapped around the edge of the support. Thus at least these connectors are preferably flexible, e.g. bend through 180° degree. Alternatively, the connectors may be part of and thus concealed within the display panel itself. In such an embodiment, such embedded connectors may magnetically or otherwise, connect to the support sheet and the connectors for the display electronics.

The connectors each comprise a part which is flexible and can be fed through the aperture. The flexible part of each column connectors 24a is inserted through the cut-outs 22a, and the flexible part of each row connector 24b is inserted through the cut-outs 22b, such that each connectors for each display panel is connected to the rear of the backplane 18. These flexible parts may be reinforced, for example by encapsulating them to protect the fragile connectors. An example of an encapsulated display is described in more detail below. Connectors 26 electrically connect connectors 24a and 24b to the driver electronics, such that each display panel is individually connected to the driver electronics. The connectors 24a,24b may connect to the connectors 26 by a magnetic attraction to ease the connection.

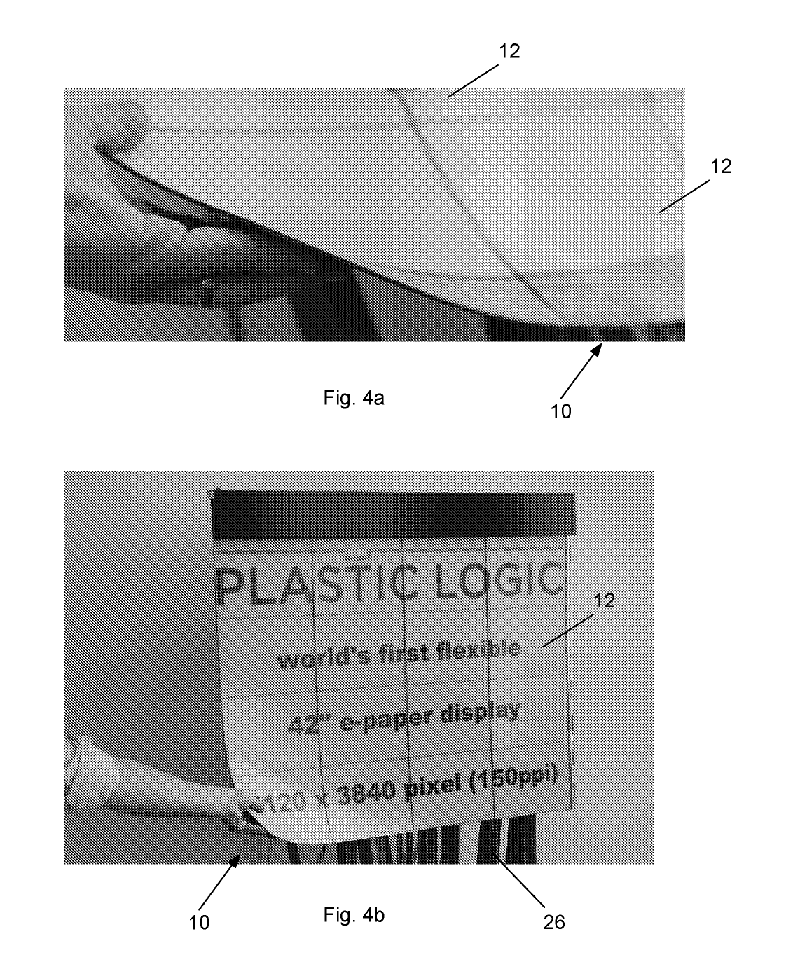

FIG. 3 shows a single display panel 12 which is coupled to a magnetic layer 14. In the illustrated embodiment, the magnetic layer has an area smaller than that of the display panel 12. However, the skilled person will understand that the size of the magnetic layer 14 may be adjusted to suit the particular arrangement.

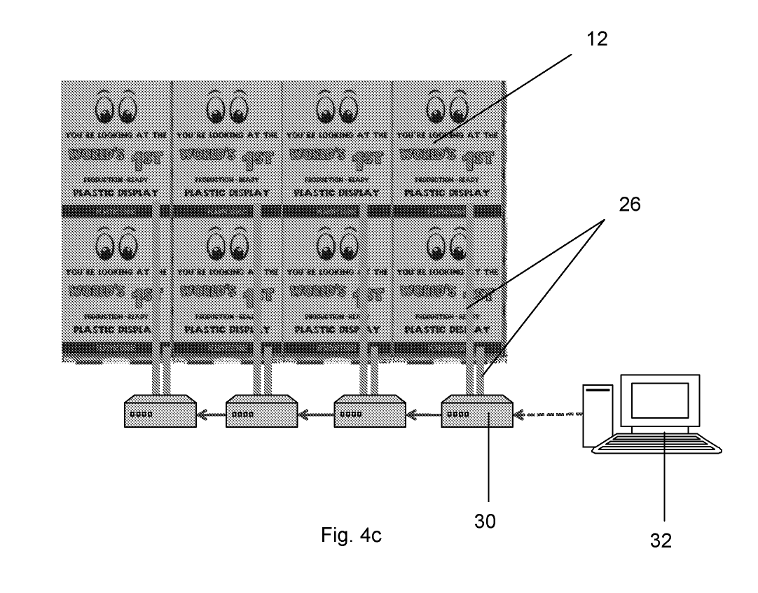

Turning now to FIGS. 4a and 4b, these show an exemplary embodiment of the display assembly formed from 16 flexible display panels. FIG. 4a depicts the flexibility and overall thickness of the display assembly 10. As discussed earlier, the display panels 12, magnetic layer 14 and magnetic support 18 are preferably all formed of flexible material, resulting in a fully flexible display assembly. In this exemplary embodiment, the display assembly has an overall thickness of less than 3 mm as the assembly is comprised of:
A magnetic support of thickness −0.5 mm;
A magnetic foil layer of thickness 0.1 mm;
Magnetic layers (laminated to the display panels) of thickness −0.5 mm; and
Flexible display panels of thickness <1 mm.

As described above, the overall thickness of the assembly may increase as the size of the assembly increases (and the number of display panels coupled to the backplane increases), as a thicker magnetic support may be required.

The magnetic layers 14 and support 18 are formed of a polymer foil material (see above), which make them at least as robust as the flexible display panels. As a result, the assembled display is also robust.

FIG. 4b shows how the assembly of display panels 12 can be used to display an image substantially continuously across the display assembly 10. Each display panel has 150 pixels per square inch. Accordingly, the four by four arrangement displays a 19.7 megapixel image (5120 by 3840) pixels.

FIG. 4c shows an alternative assembly of display panels 12 have an array of two by four panels. It will be appreciated that other sizes of array can also be used. Electrical connectors 26 electrically connect each display panel 12 individually to the driver electronics 30. There are two connectors for each panel; a gate and a source connector. In embodiments, the connections may be largely out of sight when the assembly is viewed from the front. The drive electronics unit to control the display panels may be located in the vicinity of the display assembly, and in preferred embodiments, is largely out of sight such that neither the connections 26 nor the drive electronics unit interfere with a user's view of the display when the display assembly is viewed from the front.

The drive electronics are schematically shown as four separate units but it will be appreciated that these can be combined into one unit. In this embodiment, there is one unit per two displays but it will be appreciated that a different number may be used. Where multiple units are used, one acts as the master drive unit so that it can synchronise the other units. The drive electronics may also be connected to a computer 32. This connection may be a temporary one and may be used to program the evaluation kits, i.e. for testing or pre-configuration of the display panel with the drive electronics. The computer 32 is not normally used to run a display on the display assembly but could do so; in normal use, the display is controlled by the drive electronics.

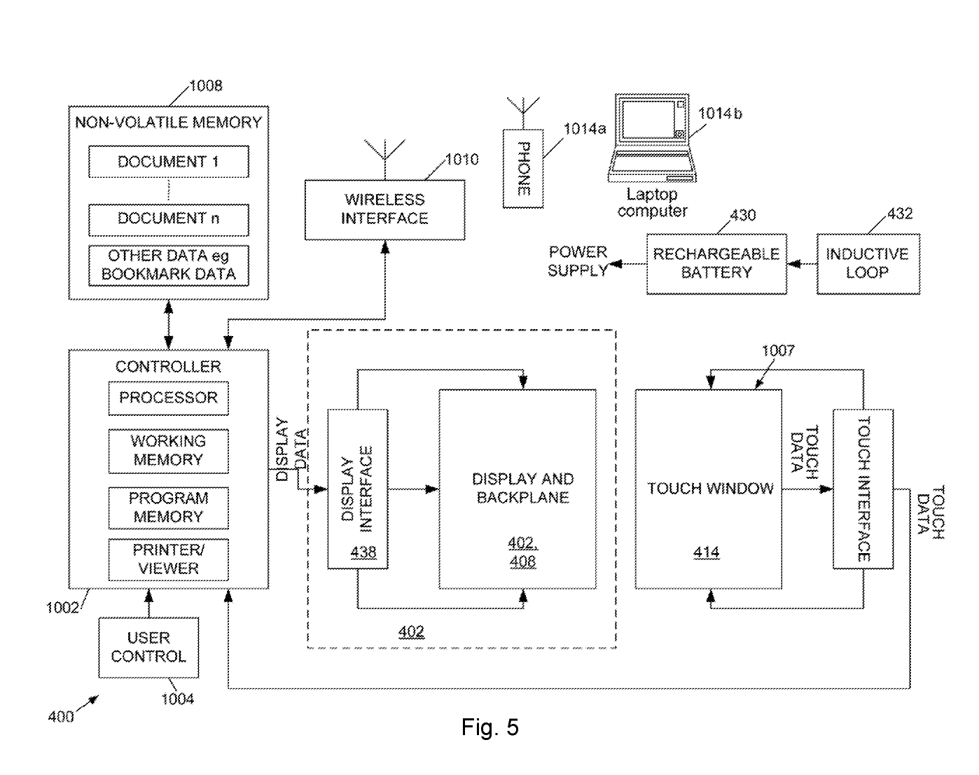

Referring now to FIG. 5, this shows a vertical cross-section view through an embodiment of a flexible display panel 400 in which electronic components of the device are distributed over a surface of the device on a flexible PCB.

In more detail, the structure comprises a substrate 402, typically a plastic such as PET (polyethyleneterephthalate) or pen(polyethelenemaphthalene) on which is fabricated a thin layer of organic active matrix pixel circuitry. The circuitry may comprise an array of organic (or inorganic) thin film transistors for example as previously described in our WO01/47045, WO2004/070466, WO01/47043, WO2006/059162, WO2006/056808, WO2006/061658, WO2006/106365 and WO2007/029028. Broadly speaking in embodiments the backplane is fabricated using solution based techniques patterned by, for example, direct-right printing, laser ablation or photolithography to fabricate the thin film transistors. In embodiments the active devices have a thickness of order 5-10 μm. In embodiments this layer has a thickness of order 50 μm and has integrated encapsulation. This substrate/backplane layer bears row and column, dataline and address conductive tracks 404, connected to the rear of substrate 402 by vias 406. We here refer to front as being towards the display surface of the device and rear as being towards the rear of the device.

A display medium 408 is attached to substrate 402, for example by adhesive. In preferred embodiments the display medium is a reflective display medium (which facilitates daylight reading), for example an electrophoretic display medium or an electrofluidic display medium. Where an electrophoretic display medium is employed a colour display may be provided by providing a colour filter array 410 over the display medium; optionally this may also perform an encapsulation function. Additionally or alternatively a moisture barrier may be provided over the display, for example comprising polyethylene and/or Aclar™ (a fluropolymer, polychlorotrifluoroethylene-PCTFE). In some embodiments the thickness of the display medium is of order 75 μm and that of the encapsulation/colour filter array of order 120 μm.

Where an electrofluidic display is employed, for example of the type available from Gamma Dynamics, Inc. Ohio USA, the colour filter array may be omitted. The use of an electrofluidic display facilitates improved brightness/contrast as well as near video display update rates and high resolution, in embodiments of order 225 pixels per inch.

In embodiments whichever display medium is employed, an edge seal 412 is provided to seal the edge of display medium 408 to the edge of the display module.

A front window 414 is provided over the display, for example comprising a thin layer of PMMA (polymethylmethacrylate) in embodiments with a thickness of order 300 μm or PET, in embodiments with a thickness of order 75 μm. Where the device is touch sensitive, this layer may also include conductive row and column lines for the touch circuitry, in embodiments employing fine line metal (FLM). The touch sensing circuitry may be operable by finger and/or a stylus. A connection to the touch sensing layer may be made by a Z-axis conductive pad 416 which connects to the touch electrodes in window 414 through CFA/encapsulation layer 410 (for example by vias, not shown) and vias 418 through substrate 402 bring the touch array connections to contact pads on the rear of substrate 402.

An adhesive layer 420 connects the substrate 402 to a flexible PCB 422 (which may incorporate circuitry 424 for an inductive stylus sensor. Connections between the contact pads on the rear of substrate 402 and the flexible PCB employ an isotropic conductive film (ACF) 426. The illustrated structure facilitates the omission of a separate moisture barrier under substrate 402, although such a barrier may be incorporated if desired.

Flexible PCB 422 carries electronic components 428, for example surface mounted components, and a thin film flexible polymer battery 430. In embodiments the PCB 422 has a thickness of order 600 μm, and the components/battery have a thickness up to 800 μm. Flexible PCB 422 also bears a conductive loop 432 around the border of the device for inductive charging of battery 430.

The components and battery are provided with a thin rear cover 434 (optional). The display and PCB module is encapsulated, for example by a gel-based potting material or encapsulant 436 which, in embodiments, fills all the internal gaps, extending around the edge of the display module, over the flexible PCB, and attaching rear cover 434.

FIG. 6 shows a block diagram of the electronics of the flexible display panel. The device comprises a controller 1002 which includes a processor, for example an ARM™ device, working memory and program memory coupled to one or more display interface integrated circuits 438 for driving the electronic paper display 408. One or more touch interface integrated circuits 1006 interface with the touch electrodes on front window 414 to provide touch data to controller 1002.

The program memory in embodiments stores processor control code to implement functions including an operating system, various types of wireless and wired interface, document retrieval, storage, annotation (via the touch interface) and export from the device. The stored code also includes code 1003 to implement a document viewer/‘printerless printing’ function, for example interfacing with corresponding driver code on a ‘host’ device.

The controller 1002 interfaces with non-volatile memory, for example Flash memory, for storing one or more documents for display and, optionally, other data such as user bookmark locations and the like. Optionally a mechanical user control 1004 may also be provided.

A wireless interface 1010, for example a Bluetooth™ or WiFi interface is provided for interfacing with a consumer electronic device such as a phone 1014a, laptop 1014b or the like. The wireless interface 1010 may comprise a Bluetooth™ RF chip and antenna.

As previously mentioned inductive loop 432 is used to charge the rechargeable battery 430 which has associated circuitry for providing a regulated power supply to the system.

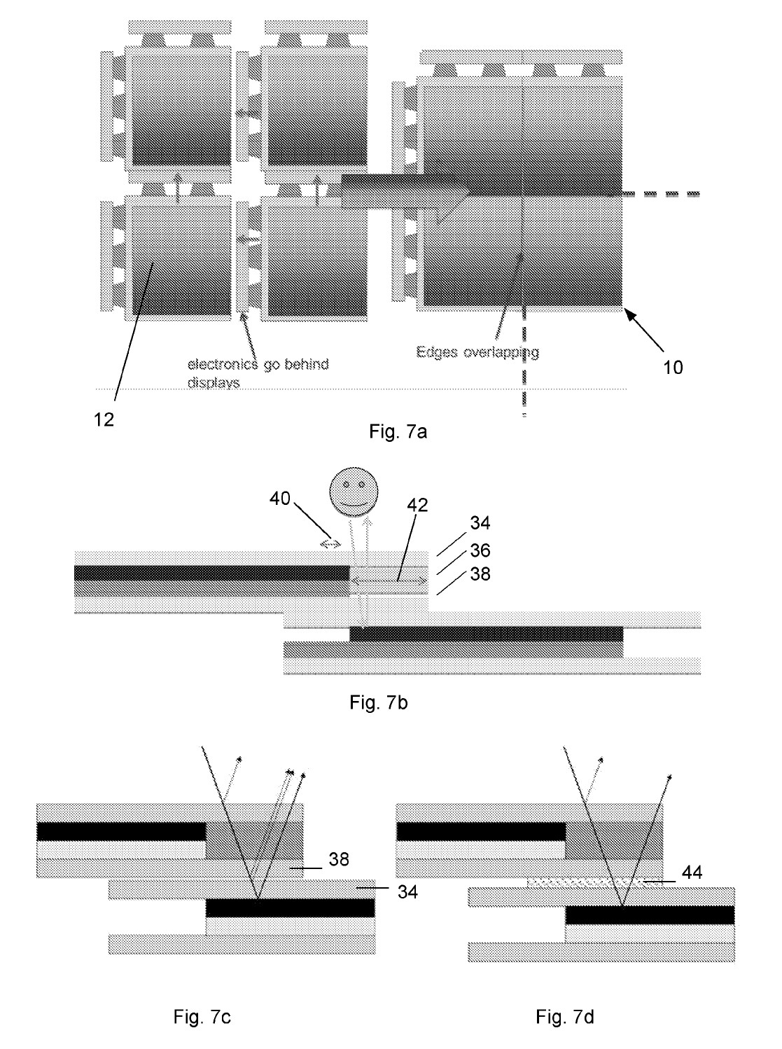

As set out above, the connectors for each display panel may be delicate and thus it may be preferred to encapsulate the connectors to protect them. Similarly, it may also be beneficial to encapsulate the display panel itself. FIGS. 7a and 7b show one arrangement for encapsulating the display panels which may be incorporated in any of the embodiments above. FIG. 7a shows how four display panels 12 are fitted side-by-side to form a two by-two display assembly. As indicated by the arrows, the connectors along the long edges of the right hand display panels slide behind the left hand panels. Similarly, the connectors along the short edge of the bottom display panels slides behind the top panels. Each panel has a frame portion which extends around some but not all sides of the display panel. When the panels are brought together, there is no gap between the panels and each panel has at least one frame portion which overlaps an adjacent panel. In the present embodiment, the frame portion extends along three edges of the panel. However, different numbers of frame portions may be used depending on the position of the panel on the assembly, e.g. panels to be used along the edges of the assembly do not need frame portions at the edges which align with the edges of the assembly. One advantage of using such an overlapping frame portion is to minimise or at least reduce the frame effect between the display panels. This increases the user's impression that the display assembly is a continuous display.

FIG. 7b shows one arrangement of the frame portion 42. In this arrangement, the display panel is encapsulated, i.e. sandwiched, between a top protective layer 34 and a rear protective layer 38. At the frame portion 42, a resin 36 is used to fill the gap between the two protective layers 36, 38 and effectively seal the two layers together. Thus, the display panel has at least one resin filled edge which forms a frame portion.

As shown in FIG. 7c, there are reflections from several of the interfaces between different layers. The unwanted reflections are shown in dotted lines and the desired reflection (i.e. from the display panel itself) is shown in solid line. The unwanted reflections may result in degradation of the contrast. Typically, there is a small air gap between the two overlapping encapsulated display panels. Unwanted reflections occur at the interfaces of this air gap with the rear surface of the rear protective layer 38 of the upper panel and with the upper surface of the upper protective layer 34 of the bottom panel. These unwanted reflections between the air-plastic interfaces are minimised as shown in FIG. 7d by including an adhesive layer 44 between the two panels. Typically, the adhesive layer is attached around the underside of the frame. This adhesive is a releasble adhesive to allow the two panels to be separated and moved as required.

One type of adhesive which is suitable is a pressure sensitive adhesive (PSA) which forms a bond between the two display panels by the application of light pressure on the upper display panel to marry the adhesive with the adherend. The bond forms because the adhesive is soft enough to flow (i.e. “wet”) to the adherend and thus such adhesives are typically termed “self-wetting” adhesives. The adhesive is preferably designed so that it can be removed without leaving residue on the lower display panel and is preferably designed to repeatedly stick and unstick. Thus, the adhesive layer will typically have low adhesion and generally can not support much weight; its primary use is to reduce the unwanted reflections. Suitable removable adhesives are commonplace and are used in many applications such as surface protection films or screen protectors. They may be made from acrylate based polymers.

The display panel is preferably an electrophoretic display. Typically such displays are active across most of the display except perhaps for a small border of perhaps just 0.5 mm which extends around the periphery of the display. The frame portion may be larger than this inactive border, e.g. perhaps five times as large, e.g. 2.5 mm. Accordingly, the frame portion needs to be transparent so that the display on the underlying adjacent display panel is not obscured. Thus, each of the top and rear layer and the resin need to be transparent. The top layer may be completely clear in which case it may be necessary to also use an antiglare or UV front cover in front of the display. Alternatively, the top layer may be an antiglare layer with reduced transparency to decrease the reflection or glare.

No doubt many other effective alternatives will occur to the skilled person. It will be understood that the invention is not limited to the described embodiments and encompasses modifications apparent to those skilled in the art lying within the spirit and scope of the claims appended hereto.

1. A display assembly comprising:
a magnetic support;
at least one display panel comprising a magnetic member; wherein said at least one display panel is releasably mounted to said magnetic support to form a display area on a front side of said support; and
an electronic driver unit connected to said support wherein said at least one display panel is electrically coupled to said electronic driver unit to drive said at least one display panel.

2. A display assembly as claimed in claim 1, wherein said electronic driver unit is mounted to a rear side of said support.

3. A display assembly as claimed in claim 1, wherein said at least one display panel comprises an electrical connector which comprises a flexible part and wherein said support comprises an aperture through which said flexible part passes to electrically connect said at least one display panel to said electronic driver unit.

4. A display assembly as claimed in claim 3, wherein there are a plurality of display panels and the support comprises a plurality of apertures which are arranged to enable each of said plurality of display panels to electrical connect to the electronic driver unit.

5. A display assembly as claimed in any one of the preceding claims claim 1 wherein the magnetic member is in the form of a magnetic layer.

6. A display assembly as claimed in claim 5 wherein the magnetic layer is mounted to a rear face of the display panel.

7. A display assembly as claimed in claim 1 wherein a foil layer is coupled between said at least one display panel and said support.

8. A display assembly as claimed in claim 1, wherein there are a plurality of display panels and wherein the electronic driver unit drives each of said plurality of display panels to display separate parts of an image whereby the plurality of display panels together display an image substantially continously across the whole assembly.

9. A display assembly as claimed in claim 1, wherein there are a plurality of display panels and wherein the electronic driver unit drives each of said plurality of display panels to display separate images.

10. A display assembly as claimed in claim 1 wherein said at least one display panel comprises an electrophoretic display.

11. A display assembly as claimed in claim 1 wherein each of the support, said at least one display panel and said magnetic member are all formed of flexible material to form a flexible assembly

12. A display assembly as claimed in claim 1 wherein the display assembly has an overall thickness of between 2 to 5 mm.

13. A display assembly as claimed in claim 1 wherein the magnetic force between the magnetic member and the magnetic support is greater than or equal to 40 cN/cm².

14. A display assembly as claimed in claim 1 wherein the magnetic member and/or the magnetic support are formed from polymer foil material.

15. A display assembly as claimed in claim 14, wherein the polymer foil material is a combination of a polymer such as PVC and a magnetic material such as barium-ferrite or strontium-ferrite.

16. A display assembly as claimed in claim 1 wherein the magnetic support comprises discrete magnetic areas.

17. A display assembly as claimed in claim 16, wherein the magnetic support has reduced thickness outside the magnetic areas whereby the magnetic support is rollable.

18. A display assembly as claimed in claim 1 comprising at least two display panels which are mounted adjacent one another on the support and wherein at least one of the display panels comprises a frame portion which overlaps the adjacent display panel.

19. A display assembly as claimed in claim 18, wherein the frame portion is transparent.

20. A display assembly as claimed in claim 1, wherein the at least one display panel is encapsulated between a front protective layer and a rear protective layer.

21. A display assembly as claimed in claim 20 comprising at least two display panels which are mounted adjacent one another on the support and wherein at least one of the display panels comprises a frame portion which overlaps the adjacent display panel and wherein the frame portion forms a sealed edge between the front protective layer and a rear protective layer.
